(19) United States
(12) Patent Application Publication
(10) Pub. No.: US 2008/0062612 A1
(43) Pub. Date: Mar. 13, 2008

(54) ELECTROSTATIC CHUCK

(75) Inventors: Ikuhisa MORIOKA, Handa-Shi (JP); Yasufumi AIHARA, Nagoya-Shi (JP)

Correspondence Address: BURR & BROWN, PO BOX 7068, SYRACUSE, NY, 13261-7068, US

(73) Assignee: NGK Insulators, Ltd., Nagoya-Shi (JP)

(21) Appl. No.: 11/850,284

(22) Filed: Sep. 5, 2007

(30) Foreign Application Priority Data
Sep. 7, 2006 (JP) 2006-243011
Sep. 21, 2006 (JP) 2006-255987

(51) Int. Cl. H01L 21/67; H01L 21/683

(52) U.S. Cl. 361/234

(57) ABSTRACT

An electrostatic chuck including lower and upper regions of a ceramic base, an embedded electrode and a resin film formed on the surface of the base. Volume resistivity of the upper region is 1×10⁹ Ω·cm to 1×10¹² Ω·cm, surface roughness of the surface of the upper region is 0.4 μm or less in centerline average roughness Ra, and the resin film is made of denatured fluorine resin. A thickness of the resin film is 1 μm or more, variations of the thickness of the resin film are ±30% or less, static friction and dynamic friction coefficients of a surface of the resin film is 0.2 or less, hardness of the resin film is 3H to F in a pencil method, and a contact angle of the resin film with water is 85° or more.

### CROSS-REFERENCE TO RELATED APPLICATION

This application is based upon and claims the benefit of priority from Patent Application No. 2006-243011 filed on Sep. 7, 2006 and Patent Application No. 2006-255987 filed on Sep. 21, 2006, in the Japanese Patent Office, of which contents are incorporated herein by reference.

### BACKGROUND OF THE INVENTION

1. Field of the Invention

The present invention relates to an electrostatic chuck.

2. Description of the Related Art

Heretofore, in a manufacturing process of a semiconductor device and a manufacturing process of a liquid crystal device, an electrostatic chuck that sucks and holds a semiconductor substrate and a glass substrate has been used. In the electrostatic chuck, there are one to suck the substrate by utilizing Coulomb force, and one to suck the substrate by utilizing Johnsen-Rahbek force. The former Coulomb force is electrostatic suction force generated between the substrate mounted on a surface of a dielectric layer of the electrostatic chuck and electrodes of the electrostatic chuck. The latter Johnsen-Rahbek force is electrostatic suction force generated between the substrate mounted on the surface of the dielectric layer of the electrostatic chuck and the surface of the dielectric layer. In the electrostatic chuck utilizing the Johnsen-Rahbek force, a minute leak current is flown through the substrate, and accordingly, for the dielectric layer, a material having predetermined volume resistivity is used.

As the material of the dielectric layer of the electrostatic chuck, ceramics, polyimide resin, and the like are used (refer to Japanese Patent Laid-Open Publication No. H8-148549 (published in 1996).

An electrostatic chuck in which the dielectric layer is formed of the polyimide resin is inferior in corrosion resistance and heat resistance to an electrostatic chuck in which the dielectric layer is formed of the ceramics, resulting in inferior durability of the resin electrostatic chuck. In such a conventional electrostatic chuck in which the resin film is directly mounted on the metal electrodes, damage and loss of the resin film result in a short circuit of high voltage power applied to the electrodes, and it becomes impossible to apply a voltage thereto. Accordingly, there has been a problem that an electrostatic suction function of the electrostatic chuck is lost immediately. Moreover, in the electrostatic chuck utilizing the Coulomb force, since variations of a thickness of the dielectric layer directly lead to variations of the suction force, it has been necessary to control the thickness of the dielectric layer more strictly than in the electrostatic chuck utilizing the Johnsen-Rahbek force.

As opposed to this, when the electrostatic chuck that uses ceramics for the dielectric layer and utilizes the Johnsen-Rahbek force is composed, the durability of the electrostatic chuck can be enhanced by the dielectric layer of ceramics, which is superior in corrosion resistance and heat resistance. Moreover, such a thickness control for the dielectric layer, which is as strict as in the electrostatic chuck utilizing the Coulomb force, is not required. Moreover, in general, in the case of applying the same voltage to both of the electrostatic chucks, the suction force of the electrostatic chuck utilizing the Johnsen-Rahbek force becomes greater than the suction force of the electrostatic chuck utilizing the Coulomb force.

However, in the electrostatic chuck in which the dielectric layer is made of ceramics, when the dielectric layer of ceramics sucks the substrate, the surface of the dielectric layer and the substrate sometimes rub against each other owing to a thermal expansion difference caused by a temperature difference between the dielectric layer and the substrate. Therefore, there has also been an apprehension that the surface of the dielectric layer may scratch a back surface of the substrate, resulting in generation of particles. There has been a case where the generated particles cause a malfunction occurs at the time of the manufacturing process of the semiconductor device. Moreover, there has been a case where the particles are adhered onto surfaces of substrates when the plurality of substrates are stacked vertically, and the adhered particles become defects in the semiconductor device, causing a device failure.

In this connection, it is an objective of the present invention to provide an electrostatic chuck that has high suction force and an excellent attachment/detachment response and is capable of achieving reduction of the generation of the particles.

### SUMMARY OF THE INVENTION

In order to achieve the above-described objective, an electrostatic chuck according to the present invention includes: a base made of ceramics; an electrode that is embedded in a vicinity of one surface of the base and generates electrostatic suction force; and a resin film formed on the surface of the base, wherein volume resistivity of the base in a region between the surface of the base and the electrode is 1×10⁹ Ω·cm to 1×10¹² Ω·cm, surface roughness of the surface of the base is 0.4 μm or less in centerline average roughness Ra, the resin film is made of denatured fluorine resin, a thickness of the resin film is 1 μm or more, variations of the thickness of the resin film are ±30% or less, a stati.c fri.ction coefficient and dynamic friction coefficient of a surface of the resin film is 0.2 or less, hardness of the resin film is 3H to F in a pencil method, and a contact angle of the resin film with water is 85° or more.

In accordance with the electrostatic chuck according to the present invention, it becomes possible to achieve the reduction of the generation of the particles on the electrostatic chuck, and the electrostatic chuck has the high suction force and the excellent attachment/detachment response.

### BRIEF DESCRIPTION OF THE DRAWINGS

The above and further objects, features and advantages of the invention will more fully appear in the detailed description of embodiments of the invention, when the same is read is conjunction with the drawings, in which:

FIGS. 1A and 1B are views showing an electrostatic chuck according to an embodiment of the present invention.

### DETAILED DESCRIPTION OF THE INVENTION

A description will be made below in detail of an electrostatic chuck according to an embodiment of the present invention by using the drawings.

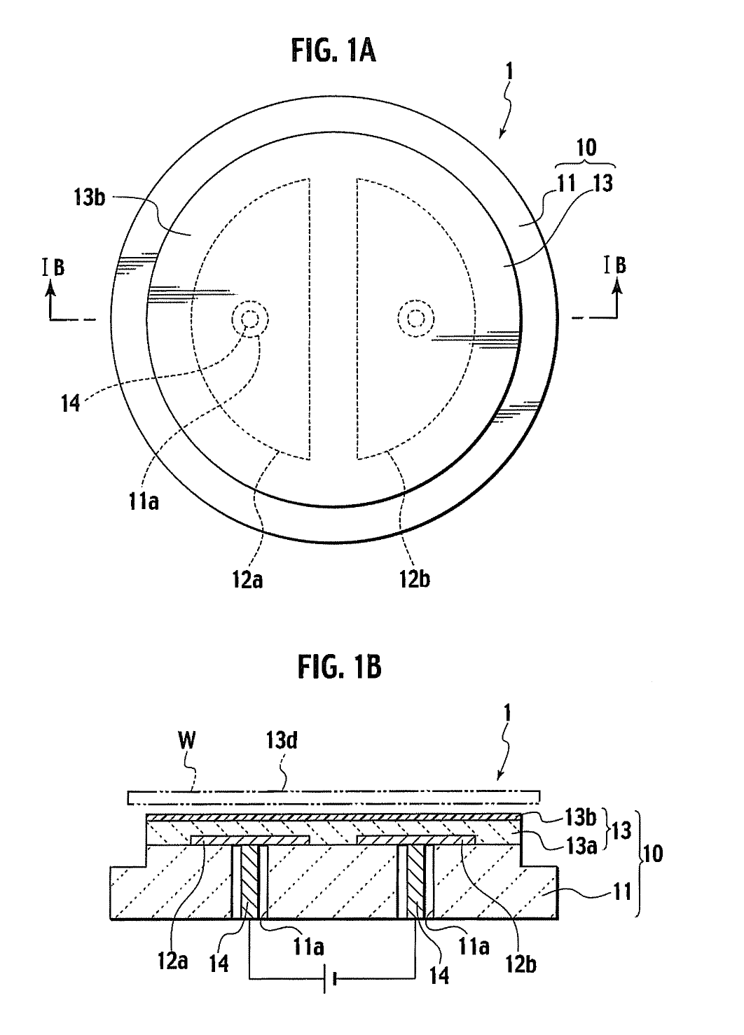

FIGS. 1A and 1B are views showing the electrostatic chuck according to the embodiment of the present invention: FIG. 1A is a plan view of the electrostatic chuck 1; and FIG. 1B is a cross-sectional view cut along a line Ib-Ib of FIG. 1A. The electrostatic chuck 1 shown in FIG. 1A and FIG. 1B includes a base 10 made of ceramics. In FIG. 1A, the base 10 is illustrated to be divided into two regions; an upper and a lower, and the lower region 11 of the base 10 is a region that becomes a support portion of the electrostatic chuck. On a lower surface of the lower region 11, terminal holes 11a which go toward electrodes 12a and 12b to be described next are formed.

On an upper surface of the lower region 11, the electrodes 12a and 12b are embedded as electrodes for generating electrostatic force. The illustrated electrodes 12a and 12b make a pair as a bipolar type.

An upper region 12a of the base 10 is formed so as to cover the upper surface of the lower region 11 and upper surfaces of the electrodes 12 and 12b. On an upper surface of the upper region 13a, a resin film 13b is formed so as to cover the upper region 13a concerned. A surface of the resin film 13b is a contact surface with which, for example, a semiconductor wafer W as a substrate to be sucked and held by the electrostatic chuck 1.

The electrodes 12a and 12b are formed between the lower region 11 and upper region 13a of the base 10, and as a result, are embedded in the base 10. The lower region 11 and upper region 13a of the base 10 are integrated across the electrodes without any gap between them. The upper region 13a and resin film 13b of the base 10, which are arranged between the electrodes 12a, 12b and the contact surface, entirely form a dielectric layer 13 of the electrostatic chuck. Then, terminals 14 are inserted into the terminal holes 11a, are bonded to the electrodes 12a and 12b individually by brazing and like, and supply electric power from an outside, thereby generate electrostatic suction force on the above-described contact surface. The illustrated electrostatic chuck 1 can be applied to both of an electrostatic chuck utilizing Coulomb force and an electrostatic chuck utilizing Johnsen-Rahbek force.

In the electrostatic chuck 1 according to this embodiment, which is shown in FIG. 1, the resin film 13b is formed on the surface of the upper region 13a of the base 10 made of ceramics. Accordingly, the semiconductor wafer W to be sucked and held on the electrostatic chuck 1 will be brought into contact with the resin film 13b softer than ceramics. Hence, even if the resin film 13b and the semiconductor wafer W rub against each other, generation of particles is small unlike in the case where the dielectric layer is made only of ceramics as in a conventional electrostatic chuck. Hence, the electrostatic chuck 1 according to this embodiment can reduce the generation of the particles.

Moreover, when volume resistivity (electrical resistivity) of the resin film 13b is 1×10¹⁵ Ω·cm or more, polarization occurs in the resin film 13b, which contributes to the generation of the Coulomb electrostatic suction force. As a result, an attachment/detachment response for the substrate can be enhanced The dielectric layer of ceramics has an electrical conductivity enough to generate the Johnsen-Rahbek force, and accordingly, the dielectric layer of ceramics also functions as the electrodes. Hence, a magnitude of the Coulomb force generated in the resin film 13b does not take a function of a distance between the electrodes and such a sucked object, but will be affected by a function of a thickness of the resin film 13b. Specifically, since the Coulomb force becomes inversely proportional to a square of the distance, the distance at which the Coulomb force is generated can be shortened in accordance with a configuration of the present invention In such a way, the electrostatic chuck of the present invention can increase the suction force though it uses the Coulomb force. In addition, even if the resin film is partially lost owing to exfoliation and the like by accident, such a ceramic dielectric layer having the electrical conductivity enough to generate the Johnsen-Rahbek force is present between both of the electrodes and the sucked object, and accordingly, the electrodes and the sucked object are not short-circuited immediately, and the suction force can be maintained stably.

Furthermore, when the volume resistivity of the resin film 13b is 1×10⁹ Ω·cm to 1×10¹² Ω·cm, besides the Coulomb force, the Johnsen-Rahbek force is generated between the sucked object and the resin film 13b by a leak current flowing to the sucked object through the resin film 13b, and accordingly, higher suction force can be generated.

Note that, when the volume resistivity of the resin film 13b is more than 1×10¹² Ω·cm to less than 1×10¹⁵ Ω·cm, it takes longer to remove electric charges by the leak current flowing in the resin layer 13b. Accordingly, even when a voltage applied to the electrostatic chuck 1 is switched off, the suction force continues to remain, and eventually, causes a failure in the detachment response for the sucked object. Therefore, it is preferable that the volume resistivity of the resin layer 13b set in a range from 1×10⁹ Ω·cm to 1×10¹² Ω·cm, or at 1×10¹⁵ Ω·cm or more.

It is desirable that the resin film 13b be fluorine resin from a view point of corrosion resistance and the like. In general, adhesion property of the fluorine resin is low, and accordingly, it is necessary to take measures for coating the resin film 13b on the surface of the ceramic-made upper region 13a with sufficient adhesive force. For example, there is considered a method of increasing adhesion between the upper region 13a and the resin film 13b by roughening the surface of the upper region 13a; however, in this method, when the surface of the upper region 13a is roughened, the surface of the resin film 13b also becomes rough essentially. Therefore, in some cases, the particles cannot be reduced since the particles are prone to be accumulated in irregularities on the surface of the resin film 13b. Moreover, there is a method of coating a primer layer on the surface of the upper region 13a, and coating the fluorine resin film 13b while interposing the primer layer therebetween; however, in this method, a thickness of the dielectric layer on an upper side of the upper region 13a is thickened too much, and accordingly, sufficient suction performance cannot be obtained in some cases.

Accordingly, in the electrostatic chuck 1 according to this embodiment, in order to enhance the adhesion between the upper region 13a made of ceramics and the resin film 13b, a denatured fluorine resin film (as a specific example, a composition of the fluorine resin and polyamide-imide) is applied to the resin film 13b. Since adhesion of the denatured fluorine resin film is good, by the fact that the resin film 13b is the denatured fluorine resin film, it becomes unnecessary to roughen the surface and to use the primer, and it becomes possible to coat the fluorine resin while finishing the surface of the upper region 13a up to a ground surface in terms of the roughness. Hence, the adhesion of the resin film 13b can be enhanced, and excellent suction performance and low particulate performance can be achieved.

It is preferable that the thickness of the denatured fluorine resin film 13b be 1 μm or more. When the thickness is less than 1 μm, the denatured fluorine resin film 13b is abraded by rubbing against the semiconductor wafer W, and accordingly, a lifetime of the resin film concerned is short. An upper limit of the thickness of the denatured fluorine resin film 13b is not particularly limited in such an electrostatic chuck that generates the Johnsen-Rahbek force, in which the volume resistivity of the resin film 13b concerned is 1×10⁹ Ω·cm to 1×10¹² Ω·cm. A thickness suitable for industrial production just needs to be selected appropriately. In such an electrostatic chuck that generates the Coulomb force, in which the volume resistivity of the resin film 13b is 1×10¹⁵ Ω·cm or more, when the thickness of the resin film 13b is too large, there is an apprehension that the suction force is decreased. Accordingly, it is preferable that the upper limit of the thickness of the resin film for the Coulomb force be approximately 50 μm.

It is preferable that in-plane variations of the thickness of the resin film 13b be ±30% or less. When the in-plane variations of the film thickness exceeds ±30%, the suction force and the attachment/detachment response are varied locally. However, even if there are such large variations as ±30%, the thickness of the resin film 13b is sufficiently smaller than the thickness of the ceramic layer, and accordingly the total thickness of the dielectric layer can be stable. The resin film 13b with the thickness variation of up to ±30% is acceptable in terms of practical use in this invention embodiment, and the tolerance of the thickness variation is extremely advantageous in terms of manufacturing.

It is preferable that a static friction coefficient and dynamic friction coefficient of the surface of the resin film 13b be individually 0.2 or less. It achieves the friction force can be made small when the semiconductor wafer W and the electrostatic chuck rub against each other, and the generation of the particles can be further reduced. Such static friction coefficient and dynamic friction coefficient can be realized by appropriately selecting the material of the denatured fluorine resin.

It is preferable that hardness of the resin film 13b be 3H to F in the pencil method. The pencil method is one to evaluate scratch harness of the resin film 13b in conformity with JIS K5600-5-4 JIS/ISO. When the hardness is 2B, the resin film 13b is too soft, and there is an apprehension that, by the fact that the semiconductor wafer W and the surface of the electrostatic chuck rub against each other, exfoliation may occur on the resin film 13b, the particles may be generated, and the lifetime of the resin film 13b may be shortened. In addition, when the hardness is B and HB, the resin film 13b is too soft, and there is an apprehension that the exfoliation may occur and the particles may be generated. When the hardness is 4H, the resin film 13b is too hard, and there is a possibility that the semiconductor wafer W may be scratched and the particles may be generated. Such hardness can be realized by appropriately selecting the material of the denatured fluorine resin.

It is preferable that a contact angle of the resin film 13b with water be 85° or more. When the contact angle is large, a contaminant is less likely to be adhered onto the resin film 13b, and further, it is possible to remove the adhered contaminant easily by washing. Hence, the contact angle is 85° or more, whereby it is easy to cleanly keep the surface of the electrostatic chuck, and the generation of the particles can be reduced. Such a contact angle can be realized by appropriately selecting the material of the denatured fluorine resin.

As the material of the denatured fluorine resin, one containing the fluorine resin and polyamide-imide, for example, “ONE COAT PAINT” (trade name) made by DuPont, or the like can be applied.

It is preferable that surface roughness of the upper surface of the upper region 13a, on which the denatured fluorine resin film 13b is to be formed, be 0.4 μm or less in centerline average roughness Ra. The denatured fluorine resin film 13b is formed in a state where the surface roughness of the upper surface concerned is maintained at the above-described level, whereby the electrostatic chuck generates less particles. When the surface roughness of the upper surface exceeds 0.4 μm in Ra, the surface of the resin film 13b is roughened, and the particles and the like, which come from the outside to formed irregularities, are prone to be accumulated therein, and accordingly, electrostatic chuck has more particles.

It is preferable that volume resistivity of the upper region 13a composing the dielectric layer 13 at room temperature be 1×10⁹ Ω·cm to 1×10¹² Ω·cm. The upper region 13a made of ceramics has such volume resistivity enough to generate the Johnsen-Rahbek force, and the dielectric layer 13 is formed by combining the upper region 13a and the resin film 13b. In such a way, as the electrostatic chuck utilizing the Coulomb force, or as the electrostatic chuck utilizing the Johnsen-Rahbek force, the electrostatic chuck according to the present invention exerts unique functions and effect, which have never seen before, and has excellent performance.

Moreover, it is preferable that, at the room temperature, volume resistivity of the entire dielectric layer 13 in which the upper region 13a and the above-described resin film 13b are combined be 1×10⁹ Ω·cm or more.

As ceramics capable of obtaining such volume resistivity and capable of enhancing durability and dielectric strength of the electrostatic chuck, it is preferable that the upper region 13a be ceramics containing aluminum nitride or aluminum oxide as a main component. For example, the upper region 13a can be formed of an aluminum nitride sintered body, aluminum oxide sintered body, a sintered body containing aluminum oxide and titanium oxide, or the like.

Furthermore, it is preferable that a difference in thermal expansion coefficient between the upper region 13a and the resin film 13b be 5×10⁻⁴/K or less. According to this, the adhesion between the ceramic layer and the resin layer can be enhanced, and the generation of an excessive leak current can be further suppressed. Note that it is not desirable that the primer layer be provided between the upper region 13a and the resin film 13b since there is an apprehension that the suction force may be insufficient though the adhesion can be enhanced.

A planar shape of the electrodes 12a and 12b is not limited to a semicircular shape as shown in FIG. 1A, and for example, may be a comb-teeth shape or a spiral shape. Note that the number of electrodes is not limited to the illustrated example where the number is two, and the number may be larger than two, or a unipolar electrode may be employed.

As the electrodes 12a and 12b, there can be used: ones formed by printing a conductive paste; wire netting; bulk bodies; thin films formed by chemical vapor deposition (CVD) or physical vapor deposition (PVD); and the like. As a conductive material of the electrodes 12a and 12b, a high melting point material such as tungsten (W), niobium (Nb), molybdenum (Mo), and tungsten carbide (WC) can be used.

The lower region 11 of the base 10, which is in contact with the electrodes 12a and 12b, can be formed of ceramics, metal, a composite material of ceramics and metal, and the like, and it is preferable that the lower region 11 be formed of the same kind of ceramic material as that of the upper region 13a.

It is preferable that the lower region 11, the upper region 13a, and the electrodes 12a and 12b become an integral sintered body. According to this, the lower region 11, the upper region 13a, and the electrodes 12a and 12b can be firmly bonded to one another, and the generation of the excessive leak current can be further suppressed. It is particularly preferable that the integral sintered body be formed by sintering using a hot press method.

A description will be made of an example of a manufacturing method of the electrostatic chuck 1 according to the embodiment of the present invention. First, a portion that becomes the lower region 11 of the base 10 is fabricated. In the fabrication of the lower region 11, first, a binder, and according to needs, water, a dispersant, and the like are added to raw material powder of ceramics, and are mixed therewith, and slurry is prepared. The raw material powder of ceramics can contain powder of aluminum nitride or aluminum oxide, which becomes the main component, and sintering aids. The obtained slurry is granulated by a spray granulation method and the like, whereby granulated powder are obtained. The obtained granulated powder are molded by a molding method such as a metal mold molding method, a cold isostatic pressing (CIP) method, or a slip cast method. A molded body thus obtained is sintered under sintering conditions (sintering atmosphere, sintering method, sintering temperature, sintering time, and the like) corresponding to the raw material powder of ceramics, and the lower region 11 of the base 10 of ceramics is fabricated.

Next, the electrodes 12a and 12b are formed on an upper surface of the portion that becomes the lower region 11. The electrodes 12a and 12b can be formed, for example, by printing the conductive paste on the surface of the lower region 11 by using a screen printing method and the like. Moreover, without being limited to the printing method, the electrodes 12a and 12b can be formed also by mounting the bulk bodies such as the wire netting on the surface of the lower region 11 of the base. Furthermore, the thin films may be formed on the surface of the lower region 11 of the base by the CVD or the PVD.

In the case of forming the electrodes 12a and 12b by the printing, it is preferable to use a conductive paste in which powder of the high melting point material such as tungsten, niobium, molybdenum, and tungsten carbide and the same type of ceramic powder as that of the upper region 13 and lower region 11 of the base 10 are mixed together. According to this, a thermal expansion coefficient of the electrodes 12a and 12b can be similar to those of the upper region 13a and the lower region 11, and bonding strength is enhanced between the electrodes 12a and 12b and the lower and upper regions 11 and 13.

Next, a portion that becomes the upper region 13a of the dielectric layer 13 is formed. In a similar way to the fabrication of the lower region 11, granulated powder are prepared by using raw material powder of ceramics, which becomes the main component of the upper region 13a. Into a metal mold or the like, the lower region 11 on which the electrodes 12a and 12b are formed is set. Then, onto the lower region 11 and the electrodes 12a and 12b, the above-described granulated powder are filled, and then are subjected to press molding, and a molded body of ceramics is formed. Alternatively, the molded body of ceramics may be formed in such a manner that a molded body of ceramics, which is separately fabricated from the granulated powder by a metallic mold pressing method, the cold isostatic pressing (CIP) method, the slip cast method, and the like, is mounted on the lower region 11, followed by pressing.

Then, the portion that becomes the lower region 11, the electrodes 12a and 12b, and the molded body of ceramics, which becomes the upper region 13a, are integrally sintered by the hot press method, whereby the integral sintered body is obtained. In such a way, the upper region 13a can be formed by the sintering Specifically, the molded body is sintered under sintering conditions corresponding to types of the lower region 11 and the molded body of ceramics while being pressured in a uniaxial direction.

Note that an order of the manufacturing steps is not limited to that of the above-described example, and for example, the sintered body may be obtained in such an order that the portion that becomes the upper region 13a of the base 10 is first molded, the electrodes 12a and 12b are formed or placed on the upper region 13, then the molded body that becomes the lower region 11 of the base 10 is formed on the upper region 13a and the electrodes 12a and 12b, and these components are integrally sintered.

Thereafter, the integral sintered body thus obtained is machined. Specifically, the upper surface of the upper region 13a is smoothened, and in addition, is subjected to a grinding process and a polishing process so that a thickness and the like of the upper region 13a can become predetermined values Moreover, the terminal holes 11a for inserting the terminals 14 into the lower region 11 are formed by a drilling process.

Next, the integral sintered body that has been already machined is washed by an organic solvent, and a contamination and oil are removed. Next, the terminals 14 are inserted into the terminal holes 11a of the lower region 11, and the terminals 14 are bonded to the electrodes 12a and 12b by brazing, whereby the electrostatic chuck, which is not subjected to the resin film coating yet, is fabricated.

Next, on the surface of the base 10, on which the resin film 13b is formed, a coating solution containing a component (hereinafter, referred to as a “resin layer component”) that becomes the resin film 13b is coated. The coating solution can contain, for example, the denatured fluorine resin as the resin film component. The coating can be performed, for example, by coating the coating solution on the surface of the base 10 by brush painting or spraying, printing the coating solution thereon by the screen printing, or immersing the surface of the base 10 into the coating solution.

Then, after being dried, the coating solution thus coated is baked. The coating solution can be baked under baking conditions (baking temperature, baking time, and the like) corresponding to the resin layer component contained in the coating solution. The coating solution containing the resin layer component is coated and baked as described above, thus making it possible to form the resin film 13b.

Note that the method of forming the resin film 13b is not limited to the above, and the resin film 13b can be formed also by adhering the resin film 13b having a sheet shape onto the upper region 13a.

### EXAMPLES

In order to fabricate the portion that becomes the lower region of the base, as the raw material powder of ceramics, mixed powder of 95 wt % aluminum nitride powder and 5 wt % yttrium oxide powder (sintering aids) was prepared. A binder was added to the raw material powder of ceramics, and was mixed therewith by using a ball mill, and slurry was obtained. The obtained slurry was sprayed and dried by using a spray dryer, and granulated powder were prepared. The obtained granulated powder were molded into a plate-like molded body by the metal molding method. The molded body was sintered by the hot press method in a nitrogen gas atmosphere. Specifically, the molded body was sintered at 1860° C. for six hours while being pressurized.

Next, as a binder, ethyl cellulose was mixed with mixed powder of 80 wt % tungsten carbide (WC) and 20 wt % aluminum nitride powder, whereby a conductive paste was prepared. By the screen printing method, the conductive paste was printed on a surface of the aluminum nitride sintered body obtained as described above, where by electrodes were formed, followed by drying.

Next, the aluminum nitride sintered body on which the electrodes were formed was set in a metal mold. Such granulated powder were filled onto the aluminum nitride sintered body and the electrodes, followed by pressurization, and the portion that becomes the upper region of the base was subjected to the press molding.

Then, the aluminum nitride sintered body, the electrodes, and the aluminum nitride sintered body, which were molded integrally, were set into a carbon-made sheath, and were sintered by the hot press method in the nitrogen gas atmosphere. Specifically, the molded body described above was held at 1860° C. for six hours while being pressurized, and was sintered integrally.

The integral sintered body thus obtained, which was formed of the base of the aluminum nitride sintered body, the electrodes, and the ceramic layer of the aluminum nitride sintered body, was machined. Specifically, the integral sintered body was subjected to the grinding process so that the thickness and the like of the upper region of the base could be predetermined values. Moreover, holes for inserting the terminals into the base were formed by the drilling process. Volume resistivity of the upper region of the base at room temperature at this point of time was 2.1×10⁹ Ω·cm, and centerline average surface roughness (Ra) of the upper surface of the ceramic layer was 0.2 μm.

Next, the integral sintered body of the base, the electrodes and the ceramic layer was washed by an organic solvent, and contamination and oil were removed. Next, the terminals were inserted into the holes of the base, and the terminals and the electrodes were bonded to each other by the brazing.

Next, on the upper surface of the upper region of the base, a coating solution of denatured fluorine resin containing fluorine resin and polyamide-imide was coated by a spray, and the coating solution was dried at 23° C. Then, the integral sintered body was baked at 350° C. to 400° C. for one hour, and an electrostatic chuck on a surface of which the resin film was formed was obtained.

A dielectric layer of the electrostatic chuck finally obtained is composed of the upper region of the base and the resin film. A plurality of the electrostatic chucks were fabricated, which were different from one another in the surface roughness of the upper region, the thickness of the resin film, the in-plane variations of the thickness of the resin film, the volume resistivity of the resin film, the hardness of the resin film, the contact angle of the resin film with water. Moreover, for each of the electrostatic chucks, the volume resistivity of the entire dielectric layer including the upper region of the base and the resin film was measured.

Suction forces and attachment/detachment responses of the obtained electrostatic chucks were evaluated in the following way. In vacuum, a silicon-made probe was brought into contact with the substrate holding surface of each of the electrostatic chucks, a voltage was applied between the electrodes of the electrostatic chuck and the silicon-made probe, and the silicon-made probe was sucked and fixed to the electrostatic chuck. The silicon-made probe was pulled up in a direction of peeling off the silicon-made probe from the substrate holding surface of the electrostatic chuck, and force required for peeling off the silicon-made probe was measured as the suction force. Moreover, a time required until the electrostatic chuck and the silicon-made probe were peeled off from each other from release of the voltage application was measured as a detachment time.

Note that an area of a tip end of the silicon made probe was set at 3 cm², and a ratio of a contact area between the silicon-made probe and the substrate contact surface was set at 4% with respect to the substrate contact surface, and then the measurement was performed at the room temperature. Moreover, the applied voltage was changed to 300V, 500V, 700V, 1000V, and 2000V.

Moreover, after a wafer was sucked onto the obtained electrostatic chuck, particles on the wafer sucking surface side were measured.

Results of these are shown in Table 1-1, Table 1-2, Table 2-1 and Table 2-2.

TABLE 1-1

| | | Example | | | | | | |
|---|---|---|---|---|---|---|---|---|
| | | 1 | 2 | 3 | 4 | 5 | 6 | 7 |
| condition | Surface roughness of ceramic | Ra 0.1 | Ra 0.2 | Ra 0.1 | Ra 0.2 | Ra 0.2 | Ra 0.2 | Ra 0.2 |
| | body [μm] | | | | | | | |
| | Film thickness of fluorine | 10 | 1 | 10 | 10 | 20 | 40 | 50 |
| | resin [μm] | | | | | | | |
| | Type of fluorine resin | Denatured | Denatured | Denatured | Denatured | Denatured | Denatured | Denatured |
| | | fluorine | fluorine | fluorine | fluorine | fluorine | fluorine | fluorine |
| | | resin | resin | resin | resin | resin | resin | resin |
| | Volume resistivity of ceramic | 3.0 × 10⁹ | 2.0 × 10⁹ | 2.0 × 10⁹ | 3.0 × 10⁹ | 1.0 × 10⁹ | 1.0 × 10⁹ | 1.0 × 10⁹ |
| | layer [Ω · cm] | | | | | | | |
| | Volume resistivity of resin | 5.0 × 10¹¹ | 1.0 × 10¹⁰ | 1.0 × 10⁹ | 1.0 × 10⁷ | 1.0 × 10¹⁵ | 1.0 × 10¹⁶ | 1.0 × 10¹⁵ |
| | layer [Ω · cm] | | | | | | | |
| | Volume resistivity of complete | 1.0 × 10¹⁰ | 3.0 × 10⁹ | 2.0 × 10⁹ | 3.0 × 10⁹ | 1.0 × 10¹³ | 5.0 × 10¹⁴ | 1.0 × 10¹⁴ |
| | dielectric layer [Ω · cm] | | | | | | | |
| | Film thickness variations [%] | ±20 | ±20 | ±20 | ±20 | ±30 | ±30 | ±30 |
| | Static friction coefficient | 0.1 | 0.1 | 0.2 | 0.1 | 0.1 | 0.1 | 0.1 |
| | (loaded with 1 kg) | | | | | | | |
| | Dynamic friction coefficient | 0.1 | 0.1 | 0.2 | 0.1 | 0.1 | 0.1 | 0.1 |
| | (loaded with 1 kg) | | | | | | | |
| | Pencil hardness | H | 3H | F | 3H | F | F | F |
| | Contact angle (with water) [°] | 100 | 90 | 100 | 95 | 85 | 85 | 85 |
| result | film | ∘ | ∘ | ∘ | ∘ | ∘ | ∘ | ∘ |
| | Suction force [Torr] | 70 | 67 | 65 | 32 | 80 | 31 | 21 |
| | Suction force variations [%] | <20 | <20 | <20 | <20 | <20 | <20 | <20 |
| | Attachment/detachment response | 0.4 | 0.5 | 0.4 | 0.2 | 0.2 | 0.2 | 0.1 |
| | [sec] | | | | | | | |
| | Particles on wafer back | 560 | 620 | 1,080 | 360 | 620 | 520 | 700 |
| | surface [number] | | | | | | | |
| | Lifetime | ∘ | ∘ | ∘ | ∘ | ∘ | ∘ | ∘ |

TABLE 1-2

| | | Example | | | | | | |
|---|---|---|---|---|---|---|---|---|
| | | 8 | 9 | 10 | 11 | 12 | 13 | 14 |
| condition | Surface roughness of ceramic | Ra 0.3 | Ra 0.4 | Ra 0.4 | Ra0.2 | Ra0.2 | Ra 0.2 | Ra 0.2 |
| | body [μm] | | | | | | | |
| | Film thickness of fluorine | 10 | 10 | 10 | 10 | 10 | 80 | 60 |
| | resin [μm] | | | | | | | |
| | Type of fluorine resin | Denatured | Denatured | Denatured | Denatured | Denatured | Denatured | Denatured |
| | | fluorine | fluorine | fluorine | fluorine | fluorine | fluorine | fluorine |
| | | resin | resin | resin | resin | resin | resin | resin |
| | Volume resistivity of ceramic | 1.0 × 10⁹ | 1.0 × 10⁹ | 1.0 × 10⁹ | 1.0 × 10⁹ | 2.0 × 10⁹ | 2.0 × 10⁹ | 1.0 × 10⁹ |
| | layer [Ω · cm] | | | | | | | |
| | Volume resistivity of resin | 1.0 × 10¹² | 1.0 × 10¹² | 1.0 × 10¹¹ | 5.0 × 10¹² | 1.0 × 10¹⁴ | 1.0 × 10¹⁰ | 5.0 × 10¹⁵ |
| | layer [Ω · cm] | | | | | | | |
| | Volume resistivity of complete | 2.0 × 10¹⁰ | 2.0 × 10¹⁰ | 7.0 × 10⁹ | 9.0 × 10¹⁰ | 1.0 × 10¹³ | 5.0 × 10⁹ | 5.0 × 10¹³ |
| | dielectric layer [Ω · cm] | | | | | | | |
| | Film thickness variations [%] | ±20 | ±20 | ±20 | ±20 | ±20 | ±20 | ±20 |
| | Static friction coefficient | 0.1 | 0.1 | 0.1 | 0.1 | 0.1 | 0.1 | 0.1 |
| | (loaded with 1 kg) | | | | | | | |
| | Dynamic friction coefficient | 0.1 | 0.1 | 0.1 | 0.1 | 0.1 | 0.1 | 0.1 |
| | (loaded with 1 kg) | | | | | | | |
| | Pencil hardness | F | F | F | F | F | 2H | F |
| | Contact angle (with water) [°] | 85 | 85 | 85 | 85 | 85 | 90 | 85 |
| result | film | ∘ | ∘ | ∘ | ∘ | ∘ | ∘ | ∘ |
| | Suction force [Torr] | 45 | 45 | 45 | 70 | 54 | 76 | 13 |
| | Suction force variations [%] | <20 | <20 | <20 | <20 | <20 | <20 | <20 |
| | Attachment/detachment response | 0.5 | 0.5 | 0.4 | 2.1 | 3.8 | 0.6 | 0.1 |
| | [sec] | | | | | | | |
| | Particles on wafer back | 1,600 | 2,400 | 1,600 | 1,260 | 1,480 | 700 | 420 |
| | surface [number] | | | | | | | |
| | Lifetime | ∘ | ∘ | ∘ | ∘ | ∘ | ∘ | ∘ |

TABLE 2-1

| | | Comparative example | | | | | |
|---|---|---|---|---|---|---|---|
| | | 1 | 2 | 3 | 4 | 5 | 6 |
| condition | Surface roughness of ceramic | Ra 0.6 | Ra 0.1 | Ra 0.2 | Ra 0.2 | Ra 0.5 | Ra 0.2 |
| | body [μm] | | | | | | |
| | Film thickness of fluorine | 20 | 20 | 70 (with | 0.1 | 10 | 0 |
| | resin [μm] | | | primer) | | | |
| | Type of fluorine resin | Denatured | FEP | FEP | Denatured | Denatured | — |
| | | fluorine | | | fluorine | fluorine | |
| | | resin | | | resin | resin | |
| | Volume resistivity of ceramic | 3.0 × 10⁹ | 3.0 × 10⁹ | 2.0 × 10⁹ | 3.0 × 10⁹ | 1.0 × 10⁹ | 1.0 × 10⁹ |
| | layer [Ω · cm] | | | | | | |
| | Volume resistivity of resin | 1.0 × 10¹² | 1.0 × 10¹⁶ | 1.0 × 10¹⁶ | 1.0 × 10¹² | 1.0 × 10¹² | — |
| | layer [Ω · cm] | | | | | | |
| | Volume resistivity of complete | 2.0 × 10¹⁰ | 2.0 × 10¹⁴ | 1.0 × 10¹⁵ | 1.0 × 10¹⁰ | 2.0 × 10¹⁰ | 1.0 × 10⁹ |
| | dielectric layer [Ω · cm] | | | | | | |
| | Film thickness variations [%] | ±20 | ±20 | ±20 | ±20 | ±20 | — |
| | Static friction coefficient | 0.2 | 0.1 | 0.1 | 0.1 | 0.1 | — |
| | (loaded with 1 kg) | | | | | | |
| | Dynamic friction coefficient | 0.2 | 0.1 | 0.1 | 0.1 | 0.1 | — |
| | (loaded with 1 kg) | | | | | | |
| | Pencil hardness | H | H | H | H | F | — |
| | Contact angle (with water) [°] | 100 | 100 | 100 | 110 | 85 | — |
| result | film | ∘ | X | ∘ | ∘ | ∘ | — |
| | Suction force [Torr] | 48 | — | 16 | 50 | 62 | 64 |
| | Suction force variations [%] | <20 | — | <20 | <20 | <20 | <20 |
| | Attachment/detachment response | 0.4 | — | 0.2 | 0.7 | 0.5 | 0.5 |
| | [sec] | | | | | | |
| | Particles on wafer back | 4,600 | — | 670 | 8,800 | 3,500 | 23,000 |
| | surface [number] | | | | | | |
| | Lifetime | ∘ | x | ∘ | x | ∘ | — |

TABLE 2-2

| | | Comparative example | | | | |
|---|---|---|---|---|---|---|
| | | 7 | 8 | 9 | 10 | 11 |
| condition | Surface roughness of ceramic | Ra 0.2 | Ra 0.2 | Ra 0.2 | Ra 0.2 | Ra 0.2 |
| | body [μm] | | | | | |
| | Film thickness of fluorine | 10 | 10 | 10 | 10 | 10 |
| | resin [μm] | | | | | |
| | Type of fluorine resin | Denatured | Denatured | Denatured | Denatured | Denatured |
| | | fluorine | fluorine | fluorine | fluorine | fluorine |
| | | resin | resin | resin | resin | resin |
| | Volume resistivity of ceramic | 3.0 × 10⁹ | 3.5 × 10⁹ | 3.0 × 10⁹ | 2.0 × 10⁹ | 1.5 × 10⁹ |
| | layer [Ω · cm] | | | | | |
| | Volume resistivity of resin | 1.0 × 10¹² | 1.0 × 10¹² | 2.0 × 10¹¹ | 5.0 × 10¹¹ | 5.0 × 10¹⁰ |
| | layer [Ω · cm] | | | | | |
| | Volume resistivity of complete | 1.0 × 10¹⁰ | 7.0 × 10¹⁰ | 4.0 × 10¹⁰ | 1.0 × 10¹⁰ | 9.0 × 10⁹ |
| | dielectric layer [Ω · cm] | | | | | |
| | Film thickness variations [%] | ±50 | ±20 | ±20 | ±20 | ±20 |
| | Static friction coefficient | 0.2 | 0.4 | 0.1 | 0.1 | 0.1 |
| | (loaded with 1 kg) | | | | | |
| | Dynamic friction coefficient | 0.2 | 0.4 | 0.1 | 0.1 | 0.1 |
| | (loaded with 1 kg) | | | | | |
| | Pencil hardness | 2H | 2H | 2B | 4H | H |
| | Contact angle (with water) [°] | 100 | 100 | 110 | 100 | 60 |
| result | film | ∘ | ∘ | ∘ | ∘ | ∘ |
| | Suction force [Torr] | 72 | 68 | 64 | 69 | 63 |
| | Suction force variations [%] | 45 | <20 | <20 | <20 | <20 |
| | Attachment/detachment response | 6.2 | 0.7 | 0.4 | 0.5 | 0.5 |
| | [sec] | | | | | |
| | Particles on wafer back | 2,400 | 4,800 | 3,000 | 3,200 | 3,300 |
| | surface [number] | | | | | |
| | Lifetime | ∘ | ∘ | x | ∘ | ∘ |

As understood from Table 1-1, Table 1-2, Table 2-1 and Table 2-2, Examples 1 to 14 according to the present invention were excellent in adhesion of the resin film, suction force and attachment/detachment response of the electrostatic chuck, particulate performance, and lifetime.

Among them, in Examples 1 to 3, 8 to 10 and 13, the volume resistivity of the resin film was in a range of 1×10⁹ Ω·cm to 1×10¹² Ω·cm, the Johnsen-Rahbek force was generated between the wafer and the resin film, and higher suction force was generated, and accordingly, the suction performance were enhanced Moreover, in Examples 5 to 7 and 14, the volume resistivity of the resin film was 1×10¹⁵ Ω·cm or more, the Coulomb force was generated between the wafer and the resin film, and higher suction force was generated, and accordingly, the suction performance were enhanced.

As opposed to this, in Comparative example 1, the upper surface of the upper region of the base was rough, and accordingly, the surface of the resin film also became rough, and dust became prone to be accumulated on microasperity thereof resulting in large particle number.

Moreover, in Comparative example 2, the adhesion was poor since the resin film was made only of the fluorine resin (FEP: fluorinated ethylene propylene resin).

Moreover, Comparative example 3 is an example where the resin film was made only of the fluorine resin and coated to be thick by using the primer. In Comparative example 3, the suction force was insufficient though it was possible to obtain good adhesion between the resin and the ceramics.

In Comparative example 4, the resin film was chipped by abrasion since the thickness of the resin film was too thin, and the lifetime of the resin film was short. Moreover, the resin was abraded, whereby the upper region of the ceramic-made base was exposed, and accordingly, the particle performance were also deteriorated.

In Comparative example 5, the upper surface of the upper region of the base was rough, and accordingly, the surface of the resin film also became rough, and the dust became prone to be accumulated on the microasperity thereof. Therefore, the particle performance were deteriorated.

In Comparative example 6, a large amount of the particles was generated since the resin film was not provided.

In Comparative example 7, the film thickness variations of the denatured fluorine resin film were ±50%, and accordingly, the in-plane variations were too large with regard to the suction force and the attachment/detachment response.

In comparative example 8, the static friction coefficient and dynamic friction coefficient of the resin film were 0.4. Accordingly, the friction force when the semiconductor wafer and the electrostatic chuck rubbed against each other was large. Hence, the particle performance were inferior.

In Comparative example 9, the resin film was as soft as 2B in the pencil method, and accordingly, the particle performance were inferior, and the lifetime was short.

In Comparative example 10, the resin film was as hard as 4H in the pencil method, and accordingly, the particle performance were inferior.

In Comparative example 11, the contact angle between the resin film and water was 60°. Accordingly, a contaminant was adhered onto the resin film, and it was difficult to remove the adhered contaminant by washing. Hence, the particle performance were inferior.

Although the electrostatic chuck according to the present invention has been described above based on the drawings and the embodiment; it is possible to implement a variety of modifications for the electrostatic chuck according to the present invention without departing from the spirit of the present invention. For example, the electrostatic chuck 1 can be made as an electrostatic chuck in which a resistance heating body is embedded in the base, thus making it possible to heat up the semiconductor wafer W. In this case, niobium, molybdenum, tungsten, and the like can be used for the resistance heating body. Moreover, ones having a linear shape, a coil shape, a band shape, a mesh shape, and the like can be used for the resistance heating body.

1. An electrostatic chuck, comprising:
a base made of ceramics;
an electrode that is embedded in a vicinity of one surface of the base and generates electrostatic suction force; and
a resin film formed on the surface of the base,
wherein volume resistivity of the base in a region between the surface of the base and the electrode is 1×10⁹ Ω·cm to 1×10¹² Ω·cm, surface roughness of the surface of the base is 0.4 μm or less in centerline average roughness Ra,
the resin film is made of denatured fluorine resin,
a thickness of the resin film is 1 μm or more,
variations of the thickness of the resin film are ±30% or less,
a static friction coefficient and dynamic friction coefficient of a surface of the resin film is 0.2 or less,
hardness of the resin film is 3H to F in a pencil method, and
a contact angle of the resin film with water is 85° or more.

2. The electrostatic chuck according to claim 1, wherein the denatured fluorine resin of the resin film contains fluorine resin and polyamide-imide.

3. The electrostatic chuck according to claim 1, wherein volume resistivity of the resin film is 1×10⁹ Ω·cm to 1×10¹² Ω·cm.

4. The electrostatic chuck according to claim 1, wherein volume resistivity of the resin film is 1×10¹⁵ Ω·cm or more.

5. The electrostatic chuck according to claim 4, wherein the thickness of the resin film is 1 μm to 50 μm.
